(19) United States
(12) Patent Application Publication
(10) Pub. No.: US 2024/0191100 A1
(43) Pub. Date: Jun. 13, 2024

(54) COMPOSITION AND METHOD FOR CONDUCTING A MATERIAL REMOVING OPERATION

(71) Applicant: SAINT-GOBAIN CERAMICS & PLASTICS, INC., Worcester, MA (US)

(72) Inventors: Renjie Zhou, Alhambra, CA (US); Chun-Lung Kuan, Anaheim, CA (US); Lin Fu, Rancho Palos Verdes, CA (US)

(21) Appl. No.: 18/535,611

(22) Filed: Dec. 11, 2023

Related U.S. Application Data
(60) Provisional application No. 63/386,971, filed on Dec. 12, 2022.

(51) Int. Cl. C09G 1/02

(52) U.S. Cl. CPC C09G 1/02

(57) ABSTRACT

In one embodiment, a polishing composition can comprise abrasive particles including zirconia, an oxidizing agent including hydroxylamine and a triazole compound, the triazole compound being selected from 1,2,4-triazole, or 1,2,3-triazole, or a combination thereof. The polishing composition can have an even a polishing selectivity of copper (Cu) to tantalum nitride (TaN) to silicon dioxide (SiO₂) of 1:1:1, with a with a selectivity variation not greater than ±50%.

### CROSS-REFERENCE TO RELATED APPLICATION(S)

This application claims priority under 35 U.S.C. § 119(e) to U.S. Patent Application No. 63/386,971, entitled “COMPOSITION AND METHOD FOR CONDUCTING A MATERIAL REMOVING OPERATION,” by Renjie ZHOU et al., filed Dec. 12, 2022, which is assigned to the current assignee hereof and incorporated herein by reference in its entirety.

### FIELD OF THE DISCLOSURE

The present disclosure relates to a composition for conducting a material removal operation, specifically an aqueous polishing composition comprising abrasive particles including zirconia and an oxidizing agent including hydroxylamine.

### BACKGROUND

Abrasive slurries have a large variety of applications, for example, for polishing of glass, ceramic, or metal materials, and are often designed for conducting a chemical mechanical planarization (CMP) process. In a typical CMP process, the relative movement of the slurry to a substrate to be polished assists with the planarization (polishing) process by chemically and mechanically interacting with the exterior surface of the substrate and removing unwanted material. Polishing is conducted until a desired smooth exterior surface with a low surface roughness is obtained. There exists a need of developing cost-efficient abrasive slurries having a high material removal rate and leading to polished substrates having a low surface roughness.

### SUMMARY OF INVENTION

In one embodiment, a polishing composition can comprise abrasive particles including zirconia, an oxidizing agent including hydroxylamine and a triazole compound, the triazole compound being selected from 1,2,4-triazole, or 1,2,3-triazol, or a combination thereof.

In another embodiment, a polishing composition can comprise abrasive particles including zirconia, and an oxidizing agent including hydroxylamine, wherein the polishing composition can be adapted that a polishing selectivity of copper (Cu) to tantalum nitride (TaN) ranges from 1:0.5 to 1:3.

In a further embodiment, a polishing composition can comprise abrasive particles including zirconia, and an oxidizing agent including hydroxylamine, wherein the polishing composition can be adapted that a polishing selectivity of Cu to silicon dioxide (SiO₂) ranges from 1:0.5 to 1:3.

In another embodiment, a polishing composition can comprise abrasive particles including zirconia, and an oxidizing agent including hydroxylamine, wherein the polishing composition can be adapted that a polishing selectivity of TaN to silicon dioxide (SiO₂) ranges from 1:0.5 to 1:3.

In yet another embodiment, a method of polishing a substrate can comprise: providing a substrate and a polishing composition; and polishing the substrate with the polishing composition using a polishing pad, wherein the polishing composition can comprise abrasive particles including zirconia, an oxidizing agent including hydroxylamine and a triazole compound, the triazole compound being selected from 1,2,4-triazole or 1,2,3-triazole.

### BRIEF DESCRIPTION OF THE DRAWINGS

The present disclosure may be better understood, and its numerous features and advantages made apparent to those skilled in the art by referencing the accompanying drawings.

FIG. 1A includes a line drawing illustrating a patterned wafer before conducting the polishing method of the present disclosure.

FIG. 1B includes a line drawing illustrating the patterned wafer shown in FIG. 1A after conducting the polishing method according to embodiments.

### DETAILED DESCRIPTION

As used herein, the terms “comprises,” “comprising,” “includes,” “including,” “has,” “having” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus.

As used herein, and unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” are employed to describe elements and components described herein. This is done merely for convenience and to give a general sense of the scope of the invention. This description should be read to include one or at least one and the singular also includes the plural unless it is obvious that it is meant otherwise.

In one embodiment, the present disclosure is directed to a polishing composition comprising abrasive particles including zirconia, an oxidizing agent including hydroxylamine, and a triazole, wherein the triazole can be 1,2,4-triazole or 1,2,3-triazole, or a combination thereof.

It has been surprisingly observed that polishing compositions containing certain combinations of zirconia particles, hydroxylamine and 1,2,4-triazone or 1,2,3-triazoe can have a desired even selectivity when polishing the materials copper, tantalum nitride (TaN) and silicon dioxide (SiO₂). Such even selectivity can be desired, for example, when polishing a copper TSV (through-silicon-via) wafer.

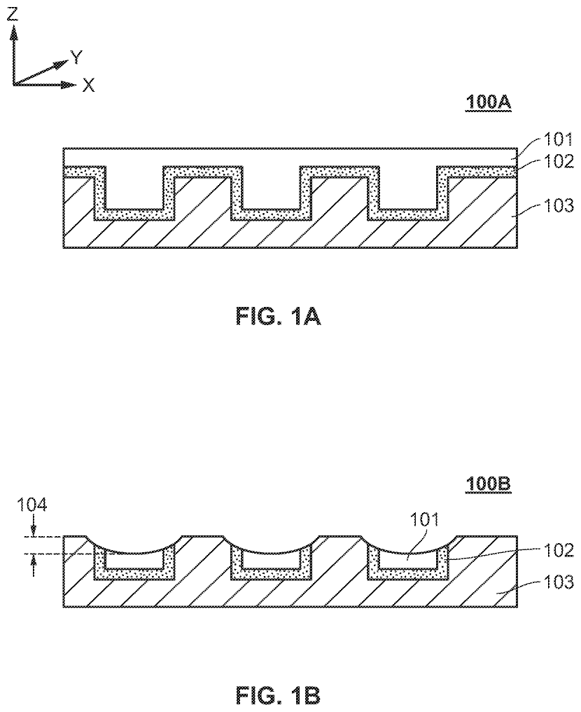

In one aspect, as illustrated in FIG. 1A, the patterned wafer (100A) can include a copper layer (101) and two dielectric layers, such as a TaN layer (102) and a SiO₂ layer (103). The copper layer can include vertical pillar sections surrounded by the TaN layer (102) and extending through a thickness direction (z) of the silicon dioxide layer (103).

The polishing composition can have the advantage that copper dishing may be very minor. As used herein, “copper dishing” means the forming of a dent or intrusion (104) after removing the protruding sections of the copper layer by the polishing process. FIG. 1B illustrates the patterned wafer shown in FIG. 1A after the polishing. It can be seen that the upper part of the copper layer has been removed, as well as portions of the TaN layer, and only the vertical pillar sections of the copper layer (101) remain, surrounded by TaN.

In one embodiment, the polishing composition can be adapted that a polishing selectivity of copper (Cu) to tantalum nitride (TaN) may range from 1:0.5 to 1:3. In a certain aspect, the polishing selectivity of Cu to TaN can be not greater than 1:0.6, or not greater than 1:0.7, or not greater than 1:0.8. In another aspect, the polishing selectivity of Cu to TaN may be at least 1:2, or at least 1:1.5, or at least 1:1.2.

In another embodiment, the polishing composition may be adapted that a polishing selectivity of copper (Cu) to silicon dioxide (SiO₂) may range from 1:0.5 to 1:3. In a certain aspect, the polishing selectivity of Cu to SiO₂ can be not greater than 1:0.6, or not greater than 1:0.7, or not greater than 1:0.8. In another aspect, the polishing selectivity of Cu to TaN may be at least 1:2, or at least 1:1.5, or at least 1:1.2.

In a further embodiment, the polishing composition of the present disclosure can have may a polishing selectivity of tantalum nitride (TaN) to silicon dioxide (SiO₂) in a range from 1:0.5 to 1:3. In a one aspect, the polishing selectivity of TaN to SiO₂ can be not greater than 1:0.6, or not greater than 1:0.7, or not greater than 1:0.8. In another aspect, the polishing selectivity of TaN to SiO₂ may be at least 1:2, or at least 1:1.5, or at least 1:1.2.

As used herein, the phrase “abrasive particles including zirconia” is interchangeable used with the phrase “zirconia particles,” if not indicated otherwise, and means that a material of the abrasive particles includes as a majority zirconia and may include in certain aspects one or more different compounds or elements.

In one embodiment, a material of the zirconia particles can include at least 80 wt % zirconia based on the total weight of the abrasive particles, or at least 85 wt % zirconia, or at least 90 wt % zirconia, or at least 95 wt % zirconia, or at least 98 wt % zirconia, or at least 99 wt % zirconia, or at least 99.5 wt % zirconia. In one particular aspect, the abrasive particles can consist essentially of zirconia. Consisting essentially of zirconia means herein that the abrasive particles include at least 99.7 wt % zirconia.

In a certain particular aspect, the abrasive particles including zirconia can comprise a Cl-containing species. The Cl-containing species can be an inorganic compound and may include chloride (Cl⁻). In a particular aspect, the amount of the chloride (Cl⁻) can be at least 1 ppm, or at least 50 ppm, or at least 100 ppm, or at least 200 ppm. In other aspect, the amount of the chloride may be not greater than 3000 ppm, or not greater than 2000 ppm, or not greater than 1000 ppm, or not greater than 500 ppm. The amount of chloride can be a value between any of the minimum and maximum values noted above. In a certain aspect, the amount of chloride can be from 70 ppm to 800 ppm.

The average particle size (D50) of the zirconia particles can be at least 30 nm, or at least 50 nm, or at least 60 nm, or at least 80 nm, or at least 100 nm, or at least 130 nm, or at least 150 nm, or at least 200 nm. In another aspect, the zirconia particles can have a D50 size of not greater than 500 nm, or not greater than 400 nm, or not greater than 300 nm, or not greater than 200 nm, or not greater than 150 nm, of not greater than 100 nm. The D50 size of the zirconia particles can be a value within a range between any of the minimum and maximum values noted above.

The amount of the zirconia particles can be at least 0.3 wt % based on the total weight of the polishing composition, or at least 0.5 wt %, or at least 0.8 wt %, or at least 1 wt %, or at least 1.3 wt %, or at least 1.5 wt %. In another aspect, the amount of zirconia particles may be not greater than 10 wt %, or not greater than 8 wt %, or not greater than 6 wt %, or not greater than 4 wt %, or not greater than 3 wt %, or not greater than 2.5 wt %, or not greater than 2.0 wt %, or not greater than 1.5 wt %. The amount of abrasive particles including zirconia can be a value within a range between any of the minimum and maximum values noted above.

In a further embodiment, the amount of hydroxylamine of the polishing composition can be at least 0.1 wt % based on the total weight of the polishing composition, or at least 0.2 wt %, or at least 0.5 wt %, or at least 1.0 wt %, or at least 1.3 wt %, or at least 1.5 wt %. In another embodiment, the amount of hydroxylamine may be not greater than 5 wt %, or not greater than 3 wt %, or not greater than 2 wt %, or not greater than 1.8 wt %, or not greater than 1.6 wt %. The amount of hydroxylamine can be a value within a range between any of the minimum and maximum values noted above.

In a particular embodiment, the oxidizing agent can consist essentially of hydroxylamine. As used herein, the oxidizing agent consisting essentially of hydroxylamine means that at least 99 wt % based on the total weight of the oxidizing agent are hydroxylamine.

In another aspect, the oxidizing agent can include at least one further oxidizing agent next to hydroxylamine. Non-limiting examples of such oxidizing agents can be a bromate, a chlorate, a iodate, an iron (III) salt (e.g., nitrate or sulfate), a cerium (IV) salt, potassium permanganate, potassium persulfate, or iodic acid.

In a further aspect, the amount of 1,2,4-triazole or 1,2,3-triazole or combination thereof can be at least 0.01 wt % based on the total weight of the polishing composition, or at least 0.03 wt %, or at least 0.05 wt %, or at least 0.07 wt %, or at least 0.1 wt %, or at least 0.13 wt %, or at least 0.15 wt %. In another aspect, the amount of the triazole may be not greater than 2 wt %, or not greater than 1.5 wt %, or not greater than 1.0 wt %, or not greater than 0.5 wt %, or not greater than 0.3 wt %. The amount of triazole compound can be a value within a range between any of the minimum and maximum values noted above.

In a particular aspect, the polishing composition of the present disclosure can comprise hydroxylamine in an amount of 0.8 wt % to 2.0 wt %, abrasive particles including zirconia in an amount of 0.3 wt % to 1.5 wt %, and 1,2,4-triazole and/or 1,2,3-triazole in an amount of 0.05 wt % to 0.5 wt % based on the total weight of the polishing composition.

The pH of the polishing composition can be at least 2.5, or at least at least 3.0, at least 3.5, at least 4.0, at least 4.5, at least 5.0, or at least 5.5. In another aspect, the pH may be not greater than 11.0, or not greater than 9.0, or not greater than 8.0, or not greater than 7.0, or not greater than 6.5, or not greater than 6, or not greater than 5.5, or not greater than 5.0. In a particular aspect, the pH can be in a range between 3.0 and 6.0.

In aspects, the polishing composition can include an optional additive, for example, a surfactant or a corrosion protecting agent.

In a particular aspect, the polishing composition of the present disclosure can be essentially free of an aminosilane compound. As used herein, essentially free of an aminosilane compound means that the polishing composition contains less than 0.01 wt % based on the total weight of the polishing composition an aminosilane compound.

In yet another aspect, the polishing composition of the present disclosure can be essentially free of an organic phosphonic acid. As used herein, essentially free of an organic phosphonic acid means that the polishing composition contains less than 0.001 wt % based on the total weight of the polishing composition of an organic phosphonic acid.

In another embodiment, the polishing composition may be essentially free of glycine. As used herein, essentially free of glycine means that the polishing composition contains less than 0.01 wt % based on the total weight of the polishing composition glycine.

In a further embodiment, the polishing composition can have a polishing selectivity of copper (Cu) to tantalum nitride (TaN) to silicon dioxide (Cu:TaN:SiO₂) of 1:1:1, with a variation not greater than 50%. As used herein, a variation of not greater than 50% means that the polishing selectivities to Cu, TaN and SiO₂ differ not more than 50% from each other. For example, of the selectivity of Copper to TaN may be 1:0.5, but not 1:0.4.

In a further embodiment, the polishing composition of the present disclosure can have a very high stability. In one aspect, the polishing composition can comprise a stability factor (SF) of at least 7. As used herein, the stability factor expresses an amount of days at a temperature of 22° C. until the amount of oxidizing agent is reduced by at least 10 wt % based on the original amount of oxidizing agent in the polishing composition. In particular aspects, the polishing composition can have a the stability factor (SF) of at least 10, or at least 15, or at least 20, or at least 30.

In one embodiment, the present disclosure is directed to a method of polishing a substrate using the polishing composition described above. The polishing method can comprise: providing the polishing composition of the present disclosure described above, bringing the polishing composition in direct contact with the substrate; and polishing the substrate surface. In one aspect, the substrate can be polished with a polishing pad, wherein the polishing pad and the substrate are moving relative to one another and the polishing composition is in contact with the substrate and the polishing pad.

In one embodiment, the temperature of the polishing composition during polishing can be at least 40° ° C., or at least 45° C., or at least 50° ° C., or at least 55° C., or at least 60° ° C., or at least 65° C. In another embodiment, the temperature of the composition during polishing may be not greater than 90° C., or not greater than 85° C., or not greater than 80° ° C., or not greater than 75° C., or not greater than 70° ° C. The temperature of the composition during polishing can be a value in a range between any of the minimum and maximum values noted above.

In a certain aspect, the substrate used in the polishing method can be a patterned wafer.

In one embodiment, the patterned wafer can be a copper TSV (through-silicon-via) wafer, including a copper, a TaN layer and a silicon dioxide layer, wherein features of the copper layer are extending at least partially through the silicon dioxide layer and are surrounded by TaN.

The polishing composition can have the advantage that copper dishing may be very minor. The “copper dishing” can be quantified by the copper dishing value Cu_{d}, which is the maximum depth measured of the dent (104) in orthogonal direction (z-direction) from the plane (x-direction) of the wafer, as illustrated in FIG. 1B. In a certain aspect, the copper dishing value Cu_{d} may be not greater than 200 Å, or not greater than 150 Å, or not greater than 100 Å, or not greater than 80 Å, or not greater than 60 Å.

As further demonstrated in the Examples below, the present disclosure provides compositions suitable as abrasive slurries for polishing a substrate, and particularly for chemical mechanical polishing a substrate.

Many different aspects and embodiments are possible. Some of those aspects and embodiments are described herein. After reading this specification, skilled artisans will appreciate that those aspects and embodiments are only illustrative and do not limit the scope of the present invention. Embodiments may be in accordance with any one or more of the embodiments as listed below.

### EMBODIMENTS

Embodiment 1. A polishing composition comprising abrasive particles including zirconia, an oxidizing agent including hydroxylamine and a triazole compound, the triazole compound being selected from 1,2,4-triazole, or 1,2,3-triazole, or a combination thereof.

Embodiment 2. A polishing composition comprising abrasive particles including zirconia, and an oxidizing agent including hydroxylamine, wherein the polishing composition is adapted that a polishing selectivity of copper (Cu) to tantalum nitride (TaN) ranges from 1:0.5 to 1:3.

Embodiment 3. A polishing composition comprising abrasive particles including zirconia, and an oxidizing agent including hydroxylamine, wherein the polishing composition is adapted that a polishing selectivity of copper (Cu) to silicon dioxide (SiO₂) ranges from 1:0.5 to 1:3.

Embodiment 4. A polishing composition comprising abrasive particles including zirconia, and an oxidizing agent including hydroxylamine, wherein the polishing composition is adapted that a polishing selectivity of TaN to SiO₂ ranges from 1:0.5 to 1:3.

Embodiment 5. The polishing composition of Embodiment 2, wherein the polishing selectivity of Cu to TaN is not greater than 1:0.6, or not greater than 1:0.7, or not greater than 1:0.8.

Embodiment 6. The polishing composition of Embodiment 2, wherein the polishing selectivity of Cu to TaN is at least 1:2, or at least 1:1.5, or at least 1:1.2.

Embodiment 7. The polishing composition of Embodiment 3, wherein the polishing selectivity of Cu to SiO₂ is not greater than 1:0.6, or not greater than 1:0.7, or not greater than 1:0.8.

Embodiment 8. The polishing composition of Embodiment 3, wherein the polishing selectivity of Cu to SiO₂ is at least 1:2, or at least 1:1.5, or at least 1:1.2.

Embodiment 9. The polishing composition of Embodiment 4, wherein the polishing selectivity of TaN to SiO₂ is not greater than 1:0.6, or not greater than 1:0.7, or not greater than 1:0.8.

Embodiment 10. The polishing composition of Embodiment 4, wherein the polishing selectivity of TaN to SiO₂ is at least 1:2, or at least 1:1.5, or at least 1:1.2.

Embodiment 11. The polishing composition of any one of the preceding Embodiments, wherein a material of the abrasive particles includes at least 80 wt % zirconia, or at least 85 wt % zirconia, or at least 90 wt % zirconia, or at least 95 wt % zirconia, or at least 98 wt % zirconia, or at least 99 wt % zirconia, or at least 99.5 wt % zirconia.

Embodiment 12. The polishing composition of Embodiment 11, wherein the material of the abrasive particles consists essentially of zirconia.

Embodiment 13. The polishing composition of any one of the preceding Embodiments, wherein an average (D50) particle size of the abrasive particles is at least 30 nm, or at least 50 nm, or at least 60 nm, or at least 80 nm, or at least 100 nm, or at least 130 nm, or at least 150 nm, or at least 200 nm.

Embodiment 14. The polishing composition of any one of the preceding Embodiments, wherein an average (D50) particle size of the abrasive particles is not greater than 500 nm, or not greater than 400 nm, or not greater than 300 nm, or not greater than 200 nm, or not greater than 150 nm, of not greater than 100 nm.

Embodiment 15. The polishing composition of any one of the preceding Embodiments, wherein an amount of the abrasive particles is at least 0.3 wt % based on the total weight of the polishing composition, or at least 0.5 wt %, or at least 0.8 wt %, or at least 1 wt %, or at least 1.3 wt %, or at least 1.5 wt %.

Embodiment 16. The polishing composition of any one of the preceding Embodiments, wherein an amount of the abrasive particles is not greater than 10 wt %, or not greater than 8 wt %, or not greater than 6 wt %, or not greater than 4 wt %, or not greater than 3 wt %, or not greater than 2.5 wt %, or not greater than 2.0 wt %, or not greater than 1.5 wt %.

Embodiment 17. The polishing composition of any one of the preceding Embodiments, wherein an amount of the hydroxylamine is at least 0.2 wt % based on the total weight of the polishing composition, or at least 0.5 wt %, or at least 1.0 wt %, or at least 1.3 wt %, or at least 1.5 wt %.

Embodiment 18. The polishing composition of any one of the preceding Embodiments, wherein an amount of the hydroxylamine is not greater than 5 wt % based on the total weight of the polishing composition, or not greater than 3 wt %, or not greater than 2 wt %, or not greater than 1.8 wt %, or not greater than 1.6 wt %.

Embodiment 19. The polishing composition of any one of the preceding Embodiments, wherein the oxidizing agent consists essentially of hydroxylamine.

Embodiment 20. The polishing composition of any one of the preceding Embodiments, wherein an amount of the triazole compound is at least 0.01 wt %, or at least 0.03 wt %, or at least 0.05 wt %, or at least 0.07 wt %, or at least 0.1 wt %, or at least 0.13 wt %, or at least 0.15 wt %.

Embodiment 21. The polishing composition of any one of the preceding Embodiments, wherein an amount of the triazole compound is not greater than 2 wt %, or not greater than 1.5 wt %, or not greater than 1.0 wt %, or not greater than 0.5 wt %, or not greater than 0.3 wt %.

Embodiment 22. The polishing composition of any one of the preceding Embodiments, wherein a pH of the polishing composition is at least 2.5, or at last 3.0, at least 3.5, at least 4.0, at least 4.5, at least 5.0, or at least 5.5.

Embodiment 23. The polishing composition of any one of the preceding Embodiments, wherein a pH of the polishing composition is not greater than 11, or not greater than 9, or not greater than 7, or not greater than 6.5, or not greater than 6, or not greater than 5.5, or not greater than 5.

Embodiment 24. The polishing composition of Embodiments 22 or 23, wherein the pH is in a range between 3.5 and 6.0.

Embodiment 25. The polishing composition of any one of the preceding Embodiments, wherein the polishing composition is essentially free of an aminosilane compound.

Embodiment 26. The polishing composition of any one of the preceding Embodiments, wherein the polishing composition is essentially free of a phosphonic acid.

Embodiment 27. The polishing composition of any one of the preceding Embodiments, wherein the polishing composition comprises hydroxylamine in an amount of 0.8 wt % to 2.0 wt %, abrasive particles including zirconia in an amount of 0.3 wt % to 1.5 wt %, and 1,2,4-triazole and/or 1,2,3-triazole in an amount of 0.05 wt % to 0.5 wt % based on the total weight of the polishing composition.

Embodiment 28. The polishing composition of any one of the preceding Embodiments, wherein the oxidizing agent includes hydroxylamine and at least one further oxidizing agent.

Embodiment 29. The polishing composition of any one of the preceding Embodiments, wherein the polishing composition is adapted that a polishing selectivity of copper to tantalum nitrate to silicon dioxide (Cu:TaN:SiO₂) is 1:1:1 with a variation not greater than +50%.

Embodiment 30. The polishing composition of any one of the preceding Embodiments, wherein the polishing composition comprises a stability factor (SF) of at least 7.

Embodiment 31. The polishing composition of Embodiment 30, wherein the stability factor (SF) is least 10, or at least 15, or at least 20, or at least 30.

Embodiment 32. The polishing composition of any one of the preceding Embodiments, wherein the abrasive particles including zirconia comprise a Cl-containing species.

Embodiment 33. The polishing composition of Embodiment 32, wherein the Cl-containing species includes chloride (Cl−).

Embodiment 34. The polishing composition of any one of Embodiments 32 or 33, wherein an amount of the Cl-containing species is at least 1 ppm or at least 5 ppm, or at least 10 ppm, or at least 30 ppm, or at least 50 ppm, or at least 100 ppm, or at least 150 ppm, or at least 200 ppm, or at least 300 ppm, or at least 500 ppm.

Embodiment 35. The polishing composition of any one of Embodiments 32-34, wherein an amount of the Cl-containing species is not greater than 3000 ppm, or not greater than 2000 ppm, or not greater than 1500 ppm, or not greater than 1000 ppm, or not greater than 600 ppm, or not greater than 300 ppm, or not greater than 100 ppm.

Embodiment 36. A method of polishing a substrate, comprising: providing a substrate and a polishing composition; and polishing the substrate with the polishing composition using a polishing pad, wherein the polishing composition comprises abrasive particles including zirconia, an oxidizing agent including hydroxylamine and a triazole compound, the triazole compound being selected from 1,2,4-triazole or 1,2,3-triazole.

Embodiment 37. The method of Embodiment 36, wherein the substrate is a patterned wafer.

Embodiment 38. The method of Embodiment 37, wherein the patterned wafer comprising copper features.

Embodiment 39. The method of any one of Embodiments 36 or 37, wherein the patterned wafer further includes a tantalum nitride (TaN) layer and a silicon dioxide layer.

Embodiment 40. The method of any one of Embodiments 36-39, wherein the polishing composition is adapted that a polishing selectivity of copper (Cu) to TaN ranges from 1:0.5 to 1:3.

Embodiment 41. The method of any one of Embodiments 36-40, wherein the polishing composition is adapted that a polishing selectivity of copper (Cu) to SiO₂ ranges from 1:0.5 to 1:3.

Embodiment 42. The method of any one of Embodiments 36-41, wherein the polishing composition is adapted that a polishing selectivity of TaN to SiO₂ ranges from 1:0.5 to 1:3.

Embodiment 43. The method of any one of Embodiments 36-42, using the polishing composition of any one of Embodiments 1-35.

### EXAMPLES

The following non-limiting examples illustrate the present invention.

### Example 1

### Polishing Composition

Polishing compositions S1, S2, S3, and S4 were prepared by combining in deionized water zirconia particles, hydroxylamine, 1,2,4-triazole, and nitric acid. The zirconia particles had an average particle size of 100 nm and contained minor amounts of chloride of 750 ppm. A summary of the types and amounts of the ingredients of the polishing compositions can be seen in Table 1.

Furthermore, comparative compositions were prepared with the same ingredients as compositions S1 to S4, except that as triazole compound was used benzotriazole instead of 1,2,4-triazole. Furthermore, in the comparative compositions the amount of zirconia, hydroxylamine, and nitric acid was varied. A summary of the comparative compositions is also shown in Table 1.

TABLE 1

| Ingredient | S1 | S2 | S3 | S4 | C1 | C2 | C3 | C4 |
|---|---|---|---|---|---|---|---|---|
| Zirconia | 0.5 | 0.5 | 1.0 | 0.5 | 1.5 | 1.0 | 1.0 | 2.0 |
| Hydroxylamine | 1.5 | 1.5 | 1.0 | 1.0 | 0.50 | 0.25 | 1.00 | 1.0 |
| 1,2,4-Triazole | 0.15 | 0.20 | 0.05 | 0.05 | | | | |
| Benzotriazole | | | | | 0.05 | 0.05 | 0.05 | 0.05 |
| Nitric Acid | 2.14 | 2.14 | 1.54 | 1.54 | 0.77 | 0.39 | 1.54 | 1.54 |
| pH | 5.52 | 5.52 | 5.38 | 5.38 | 5.64 | 5.40 | 5.57 | 5.58 |

### Polishing Tests

Polishing tests were conducted to evaluate the polishing efficiency of the compositions summarized in Table 1.

The polishing tests evaluated a) the copper removal rate, b) the tantalum nitride (TaN) removal rate and c) the silicon dioxide (SiO₂) removal rate.

A summary of the polishing results is shown in Table 2, and a description of the polishing conditions is provided in Table 3.

TABLE 2

| | | TaN | SiO₂ | |
|---|---|---|---|---|
| | Cu Removal | Removal | Removal | |
| | Rate | Rate | Rate | Selectivity |
| Composition | [Å/min] | [Å/min] | [Å/min] | Cu/TaN/SiO₂ |
| S1 | 664 | 552 | 702 | 1.0/0.8/1.1 |
| S2 | 538 | 400 | 721 | 1.0/0.7/1.3 |
| S3 | 1718 | 806 | 1150 | 1.0/0.5/0.7 |
| S4 | 1410 | 926 | 859 | 1.0/0.7/0.6 |
| C1 | 147 | 772 | 2661 | 1.0/5.3/18.1 |
| C2 | 101 | 808 | 4111 | 1.0/9.0/40.7 |
| C3 | 95 | 640 | 1165 | 1.0/6.7/12.3 |
| C4 | 157 | 674 | 1524 | 1.0/4.3/9.7 |

It was surprisingly observed that compositions S1, S2, S3, and S4 had a very even selectivity for copper, TaN and SiO₂. Comparing the ratios of the copper removal rates to the TaN removal rates, the ratios were very close to 1:1 and not lower than 1:0.5, which means the TaN removal rate was in a range of about 50% to 100% of the Copper removal rate. In contrast, in comparative examples C1 to C4, the TaN removal rate was at least four times greater than the copper removal rate, specifically between 430% to 900% higher than the copper removal rate.

Furthermore, comparing compositions S1, S2, S3, and S4 with regard to the ratio of copper removal rates to the SiO₂ removal rates, these ratios were very similar to the ratios of copper removal rate to TaN removal rate. In contrast, comparative compositions C1, C2, C3, C4 had an even greater difference between copper removal rate and SiO₂ removal rate, ranging from about 1:10 up to about 1:40 (which means a 1000% to 4000% higher SiO₂ removal rate compared to the copper removal).

Testing the copper removal rate/tantalum nitride removal rate/and silicon dioxide removal rate

All polishing experiments were conducted using as polishing tool an IPEC 472 machine, from IPEC/Westech Systems Inc. The polishing pad was polyurethane-based, type IC1000 A2 from DuPont.

For measuring the copper removal rate, as substrate was used a wafer having a diameter of 150 mm containing an upper copper film with a thickness of 1.5 microns and a 0.7 mm base Si layer underneath the copper film (Lot #GM080520-2 from Advantive Technologies).

For measuring the tantalum removal rate, a wafer having a diameter of 150 mm and an upper tantalum nitride (TaN) layer with a thickness of 0.3 μm on a Si base layer underneath the TaN layer (Lot #GM111819-6 from Advantive Technologies).

Furthermore, for measuring the silicon dioxide removal rate, a TEOS wafer from Advantive Technologies was used (Lot #GM112921-3) having a diameter of 150 mm and a 2.0 μm thick silicon dioxide film on the upper side, and a 0.7 mm Si layer underneath the silicon dioxide film.

The process parameters for conducting the polishing experiments were the same for measuring the copper removal rate, the silicon nitride removal rate, and the silicon dioxide removal rate, and are summarized in Table 3.

TABLE 3

| Parameter | Type/Value | |
|---|---|---|
| Polishing Tool | IPEC 472 | |
| Pad | IC1000 A2 | |
| Platen diameter (inches) | 2.5 | inches |
| Run time [min] | 1 | minute |

| | |
|---|---|
| Downforce [psi] | 2.0 |
| Platen Speed [rpm] | 103 |
| Carrier Speed [rpm] | 97 |
| Flow rate [ml/min] | 200 |

The pad temperature during the polishing process was maintained between 22-25° C. After processing, the wafers were cleaned using cleanroom wipes and deionized water and then dried using compressed air.

The material removal rate (MRR) was determined by the change in weight of the wafer before and after polishing. The change in weight of the wafer before and after polishing was divided by the time spent for the polishing to calculate the average material removal rate per minute. The weight of the wafers was measured using a benchtop scale.

### Example 2

Stability tests are conducted comparing slurry compositions containing zirconia particles and hydroxylamine (sample S1) with a slurry composition wherein the 1.5 wt % hydroxylamine was replaced with 1.5 wt % hydrogen peroxide (sample C5). All other ingredients of sample C5 were the same as for sample S1, including the pH.

For the stability tests, the change in the amount of oxidizing agent was measured over a time period of seven days at a temperature of 22° C. As summarized in Table 4, it was observed that the slurry composition comprising hydrogen peroxide (sample C5) already lost about 84.2 wt % percent of the hydrogen peroxide amount on the first day, only a few hours after preparing the after preparing the slurry composition. In contrast, the amount of hydroxylamine of sample S1 was stable over a time period of up to 7 days.

TABLE 4

| | Day 0 | Day 2 | Day 5 | Day 7 |
|---|---|---|---|---|
| Hydroxylamine | 1.511 wt % | 1.495 wt % | 1.470 wt % | 1.488 wt % |
| Hydrogen | 1.497 wt % | 0.2362 | 0.004 | 0.0001 |
| Peroxide | | | | |

A used herein, the stability factor expresses the amount of days at 22° C. until the amount of oxidizing agent is reduced by at least 10 wt % based on the original amount of oxidizing agent in the polishing composition.

In certain embodiments, the stability factor (SF) of the polishing compositions of the present disclosure can be at least 10, at least 20, or at least 30.

The polishing compositions of the present disclosure can have the advantage of maintaining their polishing efficiency over a long time period.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of the invention.

What is claimed is:

1. A polishing composition comprising abrasive particles including zirconia, an oxidizing agent including hydroxylamine and a triazole compound, the triazole compound being selected from 1,2,4-triazole, or 1,2,3-triazole, or a combination thereof.

2. The polishing composition of claim 1, wherein the polishing composition is adapted that a polishing selectivity of TaN to silicon dioxide (SiO₂) ranges from 1:0.5 to 1:3.

3. The polishing composition of claim 1, wherein a material of the abrasive particles includes at least 80 wt % zirconia.

4. The polishing composition of claim 1, wherein the material of the abrasive particles consists essentially of zirconia.

5. The polishing composition of claim 1, wherein an average (D50) particle size of the abrasive particles is at least 30 nm and not greater than 500 nm.

6. The polishing composition of claim 1, wherein an amount of the abrasive particles is at least 0.3 wt % and not greater than 10 wt % based on the total weight of the polishing composition.

7. The polishing composition of claim 1, wherein an amount of the hydroxylamine is at least 0.2 wt % and not greater than 5 wt % based on the total weight of the polishing composition.

8. The polishing composition of claim 1, wherein the oxidizing agent consists essentially of hydroxylamine.

9. The polishing composition of claim 1, wherein an amount of the triazole compound is at least 0.01 wt % and not greater than 2.0 wt %.

10. The polishing composition of claim 1, wherein the pH is in a range between 3.5 and 6.0.

11. The polishing composition of claim 1, wherein the polishing composition comprises hydroxylamine in an amount of 0.8 wt % to 2.0 wt %, abrasive particles including zirconia in an amount of 0.3 wt % to 1.5 wt %, and 1,2,4-triazole and/or 1,2,3-triazole in an amount of 0.05 wt % to 0.5 wt % based on the total weight of the polishing composition.

12. The polishing composition of claim 1, wherein the polishing composition is adapted that a polishing selectivity of copper to tantalum nitrate to silicon dioxide (Cu:TaN:SiO₂) is 1:1:1 with a variation not greater than +50%.

13. The polishing composition of claim 1, wherein the polishing composition comprises a stability factor (SF) of at least 7.

14. The polishing composition of claim 13, wherein the stability factor (SF) is least 15.

15. A polishing composition comprising abrasive particles including zirconia, and an oxidizing agent including hydroxylamine, wherein the polishing composition is adapted that a polishing selectivity of copper (Cu) to tantalum nitride (TaN) ranges from 1:0.5 to 1:3.

16. The polishing composition of claim 15, wherein the polishing composition further comprises a triazole compound, the triazole compound being selected from 1,2,4-triazole, or 1,2,3-triazole, or a combination thereof.

17. A method of polishing a substrate, comprising:
providing a substrate and a polishing composition; and
polishing the substrate with the polishing composition using a polishing pad, wherein the polishing composition comprises abrasive particles including zirconia, an oxidizing agent including hydroxylamine and a triazole compound, the triazole compound being selected from 1,2,4-triazole or 1,2,3-triazole.

18. The method of claim 17, wherein the substrate is patterned wafer comprises copper features and includes a tantalum nitride (TaN) layer and a silicon dioxide layer.

19. The method of claim 17, wherein the polishing composition comprises a stability factor (SF) of at least 7.

20. The method of claim 17, wherein polishing is conducted at room temperature.
